(19) United States
(12) Patent Application Publication
(10) Pub. No.: US 2025/0233564 A1
(43) Pub. Date: Jul. 17, 2025

(54) SYSTEM AND METHOD FOR CROSS-COUPLED RC NETWORKS FOR USE IN DIFFERENTIAL AMPLIFIERS AND OTHER CIRCUITS

(71) Applicant: MACOM Technology Solutions Holdings, Inc., Lowell, MA (US)

(72) Inventors: Wayne KENNAN, Lowell, MA (US); Trong PHAN, Lowell, MA (US)

(21) Appl. No.: 19/015,467

(22) Filed: Jan. 9, 2025

Related U.S. Application Data
(60) Provisional application No. 63/620,221, filed on Jan. 12, 2024.

(51) Int. Cl. H03F 3/45; H03F 1/22; H03F 3/60

(52) U.S. Cl. CPC H03F 3/45188; H03F 1/223; H03F 3/607; H03F 2203/45176

(57) ABSTRACT

Systems, circuits, and methods for a cross-coupled differential transistor amplifier. The cross-coupled transistor amplifier can be used in a multi-section amplifier, such as a 6-section differential distributed amplifier. Each cross coupled transistor includes a first transistor and a second transistor, wherein a drain of the first transistor is connected via at least one capacitor and at least one resistor to a gate of the second transistor, and a drain of the second transistor is connected via at least one additional capacitor and at least one additional resistor to a gate of the first transistor.

### CROSS REFERENCE TO RELATED APPLICATION

The present application claims the benefit of and priority, under 35 U.S.C. § 119, to U.S. Provisional Application Ser. No. 63/620,221, filed Jan. 12, 2024, entitled “SYSTEM AND METHOD FOR CROSS-COUPLED RC NETWORKS FOR USE IN DIFFERENTIAL AMPLIFIERS AND OTHER CIRCUITS” the entire disclosure of which is hereby incorporated herein by reference, in its entirety, for all that it teaches and for all purposes.

### FIELD OF THE DISCLOSURE

The present disclosure is generally directed toward circuits and, in particular, toward amplifier circuits and more particularly to differential amplifier circuits.

### BACKGROUND

Transistors are commonly used as amplifiers, or as components within an amplifier, and are used to amplify a signal. A transistor can be configured as a certain type or class of amplifier based on which terminal of the transistor is common to both the input and the output circuit. In the case of single bipolar junction transistors, the amplifier classes include common emitter, common base, and common collector. For single field-effect transistors (FETs), the amplifier classes include common source, common gate, and common drain. A number of transistors can also be coupled together or cascaded to form larger and more complex amplifier circuits including one or more amplifier sections. Examples of such amplifier circuits include differential amplifiers, distributed amplifiers, etc.

The design of an amplifier includes the evaluation of a number of operating characteristics of the amplifier, such as amplifier biasing, gain, operating bandwidth, input and output characteristics, small signal parameters, stability, and the like. The stability of an amplifier, as one operating characteristic, can depend on one or more factors such as the type (e.g., semiconductor structure and materials), biasing, power, temperature, bandwidth, and other factors related to the amplifier and the application. It is important to evaluate the stabilization characteristics and refine the stabilization approach for an amplifier design as this characteristic is often the limiting factor for key performance characteristics like bandwidth and frequency response.

A number of approaches can be relied upon to stabilize amplifiers for various purposes. As one example, a common source transistor can be stabilized with resistors placed in series with the input or output, between the source and ground, and/or between the gate and drain. In all cases, however, these stabilization techniques reduce amplifier gain or bandwidth or both. Appropriate amplifier biasing is also important for the stability of amplifiers.

The paper entitled “A 58-65 GHz Neutralized CMOS Power Amplifier With PAE Above 10% at 1-V Supply,” by Wei L. Chan and John Long, IEEE Journal of Solid State Circuits, Vol. 45, No. 3, March 2020, which is incorporated herein by reference in its entirety, details a three-stage pseudo-differential power amplifier. FIGS. 1 and illustrates a pseudo-differential cascode CMOS power amplifier stage where stability and isolation of the power amplifier are simultaneously achieved by neutralizing the parasitic Cgd capacitances of the common source transistors using cross-coupled drain-gate feedback capacitors.

In their circuit, neutralization increases the gain, increases reverse isolation and improves stability with no penalty in power consumption.

In their circuit, neutralization increases the gain with no penalty in power consumption. Unconditional stability results from the near unilateral behavior of each stage, which permits simplified inter-stage matching with on-chip coupling transformers.

### SUMMARY

Embodiments of the present disclosure are contemplated to improve amplifier circuits, and in particular differential amplifier circuits. Specifically, but without limitation, embodiments of the present disclosure aim to provide an improved cross-coupling between the gate and the drain. Even more specifically, the improvement in cross-coupling includes an RC network (one more resistors and one or more capacitors) between the gate and drain that are cross-coupled between one or more transistors, such as one or more FETs.

According to at least some embodiments, this configuration is capable of at least improving amplifier characteristics including one or more of:
stability
bandwidth
lower common mode gain
an increase in gain peaking
tunable gain peaking.

At least some of the practical applications of this technology are applicable to, without limitation, transmitters, transceivers and amplifiers, including 200 Gbps, 800 Gbps, and 1.6 Tbps PAM4 Direct Drive (Phase Amplitude Modulation with Four Levels) direct drive amplifier/communication systems.

Compared to other solutions that rely on cross-coupled capacitors alone between the gate and drain, the addition of a series resistor(s) provides a performance enhancement over capacitors by themselves.

As such, exemplary aspects have particular beneficial applicability in broadband distributed amplifier applications. And also in cascaded broadband distributed amplifier applications.

Even more specifically, the unique RC network cross-coupling has particular advantages and benefits in differential cascode amplifiers.

While cross-coupled and neutralizing capacitors in differential amplifiers are known as referenced above, the capacitors in these circuits effectively reduce one of the most troublesome parasitics in transistors—the gate-to-drain capacitance in FETs (Field effect Transistors) or the base-to-collector capacitance in bipolar transistors.

In addition to the above exemplary advantages, additional improvements include reduced reverse isolation, reduced common mode gain and generally even greater bandwidth.

One exemplary aspect adds a resistor(s) in series with the capacitor to achieve one or more of the above-noted improvements. Also, this addition of the resistor provides additional gain peaking.

This circuit configuration can be applied to a differential distributed amplifier which is even more exciting since distributed amplifiers are typically single-ended, not differential.

Cascode connections with a common source FET connected to a common gate FET are often used to enhance performance and the topology discussed herein applies either way—common source FETs with common gate FETs (cascode connection) as well as common source FETs alone. The cross coupled circuit elements are connected between the common source transistors.

These and other advantages/benefits will be apparent from the following description of the embodiments presented herein.

The preceding is a simplified summary to provide a basic understanding of some aspects and embodiments described herein. This summary is not an extensive overview of the disclosed subject matter. It is neither intended to identify key nor critical elements of the disclosure nor delineate the scope thereof. The summary is provided to present some concepts in a simplified form as a prelude to the more detailed description that is presented herein.

### BRIEF DESCRIPTION OF THE DRAWINGS

The present disclosure is described in conjunction with the appended figures, which are not necessarily drawn to scale:

FIG. 1 illustrates a first amplifier circuit according to at least some embodiments of the present disclosure;

FIG. 2 illustrates in greater detail the first amplifier circuit according to at least some embodiments of the present disclosure;

FIG. 3 illustrates a block diagram of a signal transmission system employing the first amplifier circuit according to at least some embodiments of the present disclosure; and

FIG. 4 illustrates an exemplary method for providing and tuning a first amplifier circuit according to at least some embodiments of the present disclosure.

### DETAILED DESCRIPTION

It is with respect to the above-noted challenges that embodiments of the present disclosure were contemplated and solutions to those challenges provided. In particular, a system, circuit, and method of providing/operating such circuit are provided that solve the drawbacks associated with existing amplifier circuits.

While embodiments of the present disclosure will primarily be described in connection with amplifier circuits, it should be appreciated that embodiments of the present disclosure are not so limited. Furthermore, while embodiments of the present disclosure are contemplated for use in differential distributed amplifier circuits, that embodiments of the present disclosure are not so limited.

Various aspects of the present disclosure will be described herein with reference to drawings that are schematic illustrations of idealized configurations. It should be appreciated that while particular circuit configurations and circuit elements are described herein, embodiments of the present disclosure are not limited to the illustrative circuit configurations and/or circuit elements depicted and described herein. Specifically, it should be appreciated that circuit elements of a particular type or function may be replaced with one or multiple other circuit elements to achieve a similar function without departing from the scope of the present disclosure.

It should also be appreciated that the embodiments described herein may be implemented in any number of form factors. Specifically, the entirety of the circuits disclosed herein may be implemented in silicon as a fully-integrated solution (e.g., as a single Integrated Circuit (IC) chip or multiple IC chips) or they may be implemented as discrete components connected to a Printed Circuit Board (PCB).

Moreover, it should be noted that while the following circuits will illustrate various resistors and capacitors that cross-couple the transistors in each section of a distributed amplifier, these resistors and capacitors within each section and/or between each section can have the same or different values. For example, the resistors and/or capacitors in one section could have the same values, respectively, but those values differ for other sections. Alternatively, the resistors and/or capacitors could have the same values, respectively, for each section. Alternatively still, some sections may have matched or similar resistor and/or capacitor values, respectively, while other sections have differently matched or similar resistor and/or capacitor values, respectively. Alternatively still, each transistor can be paired with resistor and/or capacitor values that are different than one or more other transistor resistor and/or capacitor values.

For example, the resistors (designated Rxc for resistor, cross-coupled) and capacitors (designated Cxc for capacitor, cross-coupled) can be configured in any one more of the following non-conflicting, non-limiting ways:
(i) Each section has different Rxc and Cxc values
(ii) Each section has the same Rxc and Cxc values
(iii) Each section has different Rxc values but the same Cxc values
(iv) Each section has the same Rxc values but different Cxc values
(v) Within each section there are the same Rxc values
(vi) Within each section there are different Rxc values
(vii) Within each section there are the same Cxc values
(viii) Within each section there are different Cxc values

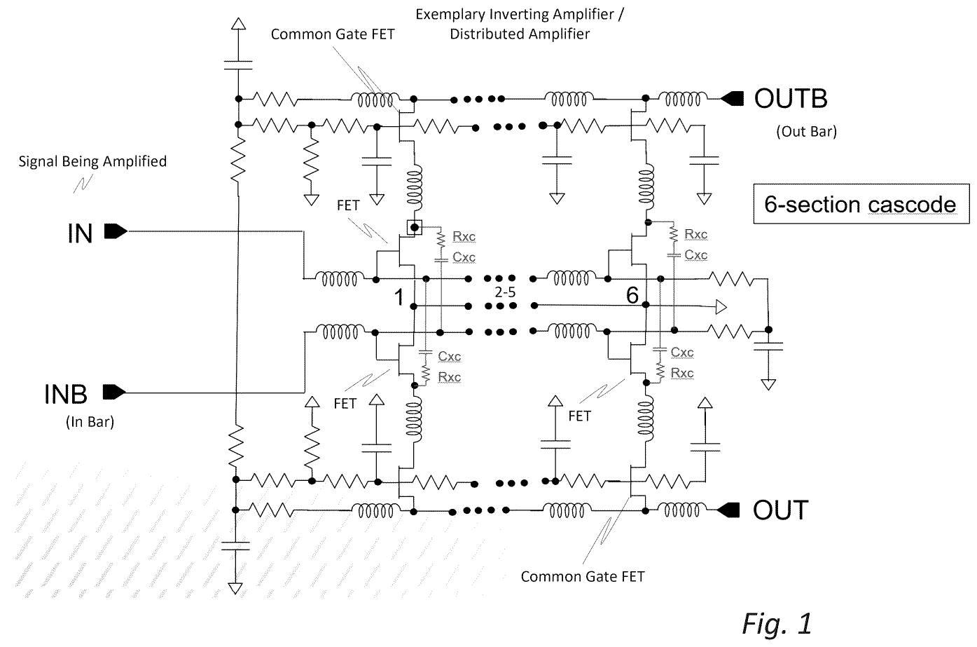

FIG. 1 illustrates an exemplary amplifier circuit that happens to be a distributed differential amplifier circuit with an inductor at the input of each transistor. The IN represents the input signal being amplified and the OUT the output. OUTB is shown as this exemplary circuit is an inverting amplifier. For this exemplary circuit, there are six sections in a cascode configuration. Each section includes a pair of cross-connected common source transistors that feed into the next, downstream section.

Within each section, each common source transistor is cross-coupled via a series connected resistor-capacitor circuit between the drain of a first transistor and a gate of a second transistor and the drain of the second transistor and the gate of the first transistor. In this implementation, each section is a cascode with a common source FET and common gate FET but this invention can be applied if there are only common source transistors, i.e., not a cascode. Each common source transistor drain within each section is respectively connected to thesource of a common gate FET as is known in cascode amplifiers.

Other optional additions to this circuit include electro-static dissipation components, current mirrors, bias circuits, etc.

In general, the selection of values for the resistor and/or capacitor can be selected to attempt to cancel out the gate-to-drain capacitance of the respective common source transistor to which the resistor and capacitor (e.g., RC circuit) are connected. However, the circuit is not limited as such and selection of other values for other purposes is possible. The trade of off the selected values to cancel out the gate-to-drain capacitance with stability of the circuit can be balanced.

Of note, one can optionally optimize the layout to reduce the distance between the node of the drain and the node of the gate to try and reduce inductive effect.

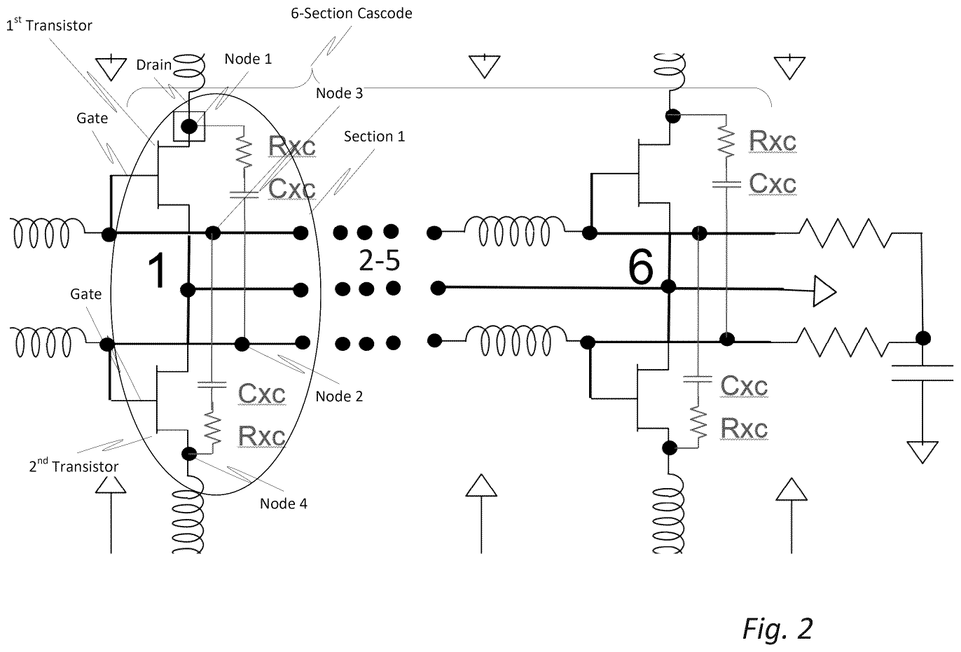

FIG. 2 illustrates in greater detail one section of the amplifier. This section includes the 1^{st} common source transistor, 2^{nd} common source transistor and the associated resistor-capacitor circuits. As mentioned above, optionally one can reduce the distance between node 1 and node 2, as well as the distance between node 3 and node 4 to improve the performance of the series-connected resistor-capacitor circuits.

FIG. 2 further illustrates that there can be any number of sections in a distributed amplifier implementation, here 6 sections are illustratively shown, with the first section feeding into the next section and so on in a cascaded fashion. Each section has a similar component layout and the middle sections have similarly structured inputs and outputs.

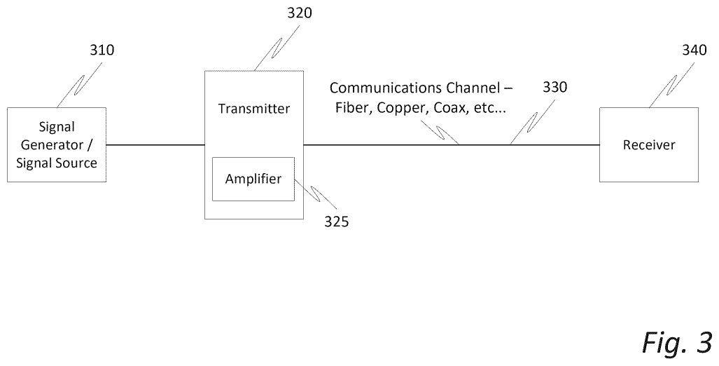

FIG. 3 illustrates an exemplary environmental diagram where the circuit of FIG. 1 can be employed. In particular, the environment is a communications topology comprising a signal generator/signal source 310. The signal generator/signal source 310 is connected to a transmitter 320 that includes the amplifier circuit of FIG. 1. The transmitter 320 is connected to a communications channel 330 such as a fiber communications channel, a copper communications channel, a coax communications channel, or in general any communication media over which a signal can be communicated. At the receiving end of the communications channel 330 is a receiver 340 configured to receive the signal from the signal generator/signal source 310.

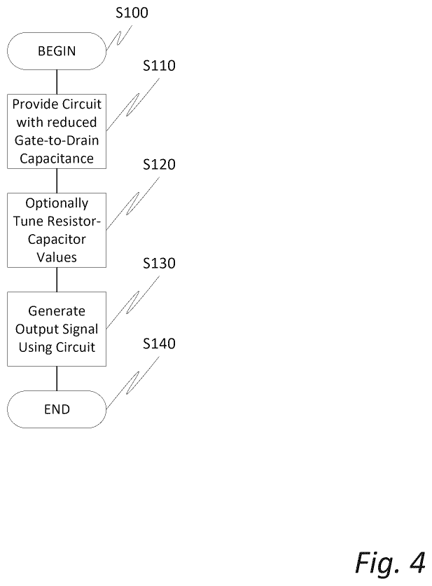

FIG. 4 is a flowchart illustrating a method for providing and utilizing a reduced gate-to-drain capacitance transistor. In particular, control begins in step S100 and continues to step S110. In Step S110, a circuit is provided that has a reduced gate-to-drain capacitance. At a minimum, this circuit includes a transistor with a resistor and capacitor that are cross-coupled with another transistor. It could also include an amplifier similar to that illustrated in FIG. 1 or in general any circuit that includes cross-coupled capacitors as disclosed.

Next, in step S120, and optionally, one or more of the resistor and capacitor values can be adjusted to reduce gate-to-drain capacitance. Then, in step S130, an output signal can be generated using the cross-coupled circuit with control continuing to step S140 were control ends.

Specific details were given in the description to provide a thorough understanding of the embodiments. However, it will be understood by one of ordinary skill in the art that the embodiments may be practiced without these specific details. In other instances, well-known circuits, processes, algorithms, structures, and techniques may be shown without unnecessary detail in order to avoid obscuring the embodiments.

While illustrative embodiments of the disclosure have been described in detail herein, it is to be understood that the inventive concepts may be otherwise variously embodied and employed, and that the appended claims are intended to be construed to include such variations, except as limited by the prior art.

1. An amplifier circuit, comprising:
a plurality of amplifier sections; and
each amplifier section includes a pair of cross-coupled transistors where the cross coupling includes at least one capacitor and at least one resistor.

2. The amplifier circuit of claim 1, wherein a drain of a first transistor of the pair of cross-coupled transistors is connected via a series connected resistor and capacitor to a gate of a second transistor.

3. The amplifier circuit of claim 2, wherein a drain of a second transistor of the pair of cross-coupled transistors is connected via another series connected resistor and capacitor to a gate of the first second transistor.

4. The amplifier circuit of claim 3, wherein each amplifier section includes a pair of cross-coupled transistors.

5. The amplifier circuit of claim 4, wherein each amplifier section is a cascode with a common source and common gate FET.

6. The amplifier circuit of claim 5, wherein each transistor drain within each amplifier section is respectively connected to a source of a common gate FET or each common source transistor drain within each amplifier section is respectively connected to a source of a common gate FET.

7. The amplifier circuit of claim 1, wherein the pair of cross-coupled transistors are FETs.

8. The amplifier circuit of claim 1, wherein the amplifier circuit is a differential amplifier circuit.

9. The amplifier circuit of claim 8, wherein the amplifier is configured as a distributed amplifier.

10. A circuit comprising:
a first transistor; and
a second transistor, wherein a drain of the first transistor is connected via at least one capacitor and at least one resistor to a gate of the second transistor, and a drain of the second transistor is connected via at least one additional capacitor and at least one additional resistor to a gate of the first transistor.

11. The circuit of claim 10, wherein sources of the first and the second transistor are connected.

12. The circuit of claim 10, wherein the at least one capacitor and the at least one resistor are series connected.

13. The circuit of claim 10, wherein the at least one additional capacitor and the at least one additional resistor are series connected.

14. The circuit of claim 10, wherein the circuit is included as a portion of an amplifier.

15. The circuit of claim 10, wherein the at least one capacitor and the at least one resistor reduce a gate-to-drain capacitance of the first transistor.

16. The circuit of claim 10, wherein the at least one additional capacitor and the at least one additional resistor reduce a gate-to-drain capacitance of the second transistor.

17. The circuit of claim 10, wherein the circuit is configured for a cascode operation.

18. A circuit comprising:
means for reducing a gate-to-drain capacitance in a cascode amplifier section.

19. A method for generating a signal comprising:
providing a circuit with a pair of cross-connected transistors, wherein the cross connected transistors include a first transistor and a second transistor, wherein a drain of the first transistor is connected via at least one capacitor and at least one resistor to a gate of the second transistor, and a drain of the second transistor is connected via at least one additional capacitor and at least one additional resistor to a gate of the first transistor; and
generating an output signal using at least the provided circuit.

20. The method of claim 19, further comprising:
determining values for the at least one capacitor and the at least one resistor; and
determining values for the at least one additional capacitor and at least one additional resistor.
